(19) United States
(12) Patent Application Publication
(10) Pub. No.: US 2023/0191555 A1
(43) Pub. Date: Jun. 22, 2023

(54) CHEMICAL MECHANICAL POLISHING APPARATUS AND METHOD USING THE SAME

(71) Applicant: Samsung Electronics Co., Ltd., Suwon-si (KR)

(72) Inventors: Chaelyoung Kim, Hwaseong-si (KR); Jinyoung Park, Suwon-si (KR); Jaehyug Lee, Hwaseong-si (KR); Hoyoung Kim, Seongnam-si (KR)

(21) Appl. No.: 17/940,403

(22) Filed: Sep. 8, 2022

(30) Foreign Application Priority Data
Dec. 22, 2021 (KR) 10-2021-0185049

(51) Int. Cl. B24B 37/04; B24B 37/10; B24B 57/02; H01L 21/3105

(52) U.S. Cl. CPC B24B 37/046; B24B 37/105; B24B 37/044; B24B 57/02; H01L 21/31053; H01L 21/3212

(57) ABSTRACT

A chemical mechanical polishing apparatus, includes: a platen having a polishing pad attached to an upper surface thereof, and rotatably installed in one direction by a driving means, a slurry supply unit supplying a slurry including an abrasive and an additive having a zeta potential of a first polarity to the polishing pad, an electrode disposed below the polishing pad, a power supply unit applying a voltage including a DC pulse of a second polarity, opposite to the first polarity, to the electrode, and a polishing head installed on the polishing pad, and rotating a semiconductor substrate in contact with the polishing pad.

### CROSS-REFERENCE TO RELATED APPLICATION(S)

This application claims benefit of priority under 35 U.S.C. § 119 to Korean Patent Application No. 10-2021-0185049, filed on Dec. 22, 2021, in the Korean Intellectual Property Office, the disclosure of which is incorporated herein by reference in its entirety.

### BACKGROUND

### 1. Field

The present inventive concept relates to a chemical mechanical polishing apparatus and a method using the same.

### 2. Description of Related Art

A chemical mechanical polishing (CMP) process is a process of planarizing a surface of a substrate by combining a mechanical polishing effect of an abrasive and a chemical reaction effect of an acid or base solution.

The CMP process is used for planarization of various materials, such as an interlayer dielectric (ILD), a polishing process of a silicon oxide film for shallow trench isolation (STI) purposes, a tungsten (W) plug forming process, and a copper interconnection process.

### SUMMARY

An aspect of the present inventive concept is to provide a chemical mechanical polishing apparatus having improved planarization efficiency of a polishing target film in a CMP process.

An aspect of the present inventive concept is to provide a chemical mechanical polishing method in which flatness of a polishing target film is improved in a CMP process.

According to an aspect of the present inventive concept, a chemical mechanical polishing apparatus includes: a platen having a polishing pad attached to an upper surface thereof, and rotatably installed in one direction by a driving means, a slurry supply unit configured to supply a slurry including an abrasive and an additive having a zeta potential of a first polarity to the polishing pad, an electrode disposed below the polishing pad, a power supply unit configured to apply a voltage including a DC pulse of a second polarity, opposite to the first polarity, to the electrode, and a polishing head installed on the polishing pad, and configured to rotate a semiconductor substrate in contact with the polishing pad.

According to an aspect of the present inventive concept, a chemical mechanical polishing apparatus includes: a platen having a polishing pad attached to an upper surface thereof, a slurry supply unit configured to supply a slurry including an abrasive and an additive having a zeta potential of a first polarity to the polishing pad, an electrode disposed below the polishing pad, a voltage supply unit configured to apply a voltage of a second polarity, opposite to the first polarity, to the electrode, the voltage supply unit configured to adjust the voltage to adjust intensity of an electrical field applied to the abrasive and the additive at the electrode, and a polishing head installed on the polishing pad, and configured to rotate a semiconductor substrate in contact with the polishing pad, wherein the abrasive and the additive have different vertical distributions between the polishing pad and the semiconductor substrate by the electrical field.

According to an aspect of the present inventive concept, a chemical mechanical polishing apparatus includes: a platen having a polishing pad attached to an upper surface thereof, a slurry supply unit configured to supply a slurry including an abrasive and an additive having a zeta potential of a first polarity to the polishing pad, an electrode disposed below the polishing pad, a power supply configured to apply a voltage of the first polarity and a voltage of a second polarity, opposite to the first polarity, to the electrode, and a polishing head installed on the polishing pad, and configured to rotate a semiconductor substrate including a polishing target film having a zeta potential of the second polarity in contact with the polishing pad, wherein the power supply unit is configured to alternately apply a voltage of the first polarity and a voltage of the second polarity.

According to an aspect of the present inventive concept, a chemical mechanical method includes: preparing a polishing target film on a semiconductor substrate, preparing a slurry including an abrasive and an additive having a zeta potential of a first polarity and having different charge densities, and applying a voltage of a second polarity, opposite to the first polarity, to the slurry and polishing the polishing target film with the slurry, wherein the polishing the polishing target film with the slurry includes adjusting the voltage to adjust a magnitude of an electrical field applied to the slurry, to control a vertical distribution of the abrasive and the additive included in the slurry.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram schematically illustrating a chemical mechanical polishing apparatus according to an example embodiment;

FIG. 2 is a diagram schematically illustrating any one platen of FIG. 1;

FIG. 3 is a cross-sectional view of the platen of FIG. 2;

FIG. 4 is a diagram illustrating a process in which an abrasive and an additive move when a pulse is not applied to the electrode;

FIG. 5 is a diagram illustrating a process in which an abrasive and an additive move when a pulse of a second polarity is applied to an electrode;

FIG. 6 is a diagram illustrating a process in which an abrasive and an additive move when a pulse of a first polarity is applied to an electrode;

FIGS. 7A to 7C are diagrams specifically illustrating a process in which an abrasive and an additive are adsorbed on a surface of a polishing target film when pulses of a first polarity and a second polarity are applied;

FIGS. 8A to 8D show various examples of pulses applied to an electrode;

FIGS. 9A and 9B show modified examples of the pulse applied to an electrode; and

FIG. 10 is a flowchart schematically illustrating a chemical mechanical polishing method according to an example embodiment.

### DETAILED DESCRIPTION

Hereinafter, embodiments of the present inventive concept will be described with reference to the accompanying drawings.

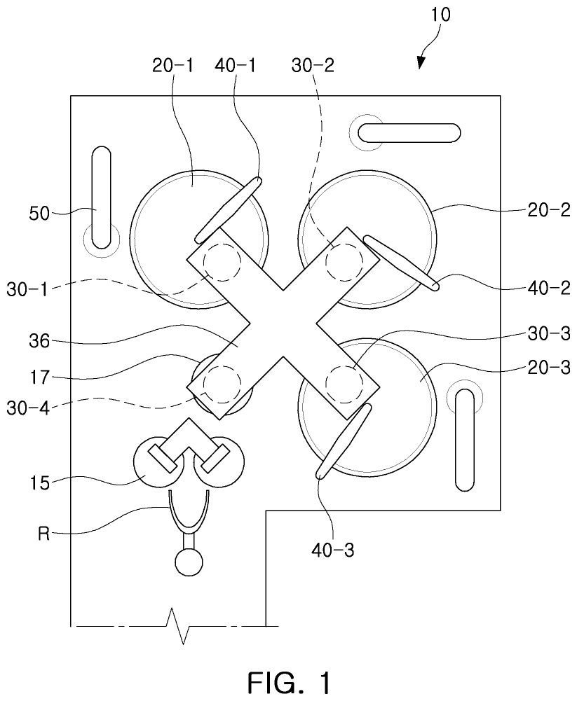

FIG. 1 is a diagram schematically illustrating a chemical mechanical polishing apparatus according to an example embodiment of the present inventive concept.

Referring to FIG. 1, a chemical mechanical polishing apparatus 10 may include first to third platens 20-1, 20-2, and 20-3, first to fourth polishing heads 30-1, 30-2, 30-3, and 30-4, and first to third slurry supply units 40-1, 40-2, and 40-3. The chemical mechanical polishing apparatus 10 may further include a multi-head carousel 36, first to third conditioners 50, a semiconductor substrate inversion unit 15, a loading-unloading unit 17, and a robot R.

A polishing pad may be mounted to each of the first to third platens 20-1, 20-2, and 20-3. First to third polishing heads 30-1, 30-2, and 30-3, and first to third slurry supply units 40-1, 40-2, and 40-3 may be disposed in the first to third platens 20-1, 20-2, and 20-3, respectively.

The first to fourth polishing heads 30-1, 30-2, 30-3, and 30-4 may be attached to a rotatable multi-head carousel 36 to be moved onto the first to third platens 20-1, 20-2, and 20-3 and the loading-unloading unit 17. The first to fourth polishing heads 30-1, 30-2, 30-3, and 30-4 may be configured to independently perform a raising and lowering operation and a rotation operation, respectively. For example, the first to fourth polishing heads 30-1, 30-2, 30-3, and 30-4 may be configured to be independently raised and lowered and to be independently rotated. The semiconductor substrate inversion unit 15 may invert and transfer a semiconductor substrate to the loading-unloading unit 17 for polishing, or may invert and unload the semiconductor substrate from the loading-unloading unit 17. The robot R may transfer a semiconductor substrate to be polished to the semiconductor substrate inversion unit 15, or may unload the polished semiconductor substrate from the semiconductor substrate inversion unit 15. The first to third conditioners 50-1, 50-2, and 50-3 may adjust a state of the polishing pad to maintain a constant polishing rate.

The chemical mechanical polishing apparatus 10 illustrated in FIG. 1 exemplarily illustrates a polishing apparatus having a plurality of platens on which an example embodiment of the present inventive concept may be performed. An example embodiment of the present inventive concept may be performed in a chemical mechanical polishing apparatus having various structures. For example, an example embodiment of the present inventive concept may be performed in a chemical mechanical polishing apparatus in which the plurality of platens are disposed linearly.

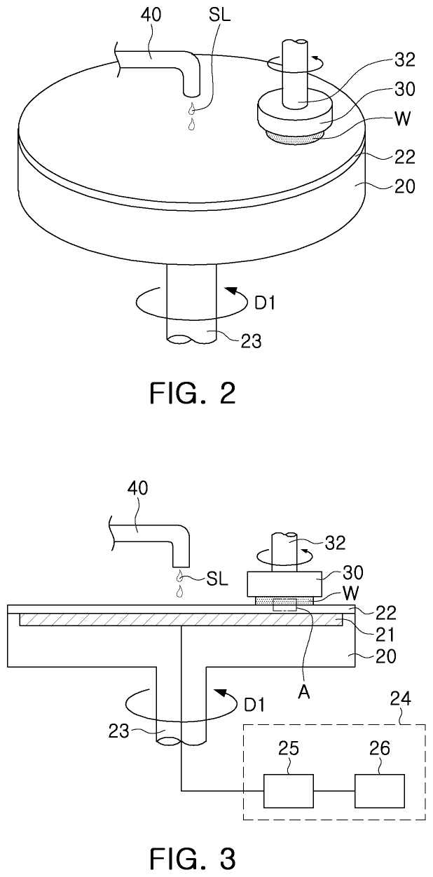

Hereinafter, with reference to FIGS. 2 and 3, the chemical mechanical polishing apparatus 10 will be described with reference to any platen 20 among the first to third platens 20-1, 20-2, and 20-3.

As illustrated in FIG. 2, the polishing head 30 and the slurry supply unit 40 may be sequentially disposed on the platen 20 in a rotation direction D1, respectively.

Referring to FIGS. 2 and 3, the platen 20 may have a polishing pad 22 attached to an upper surface of the platen 20 to provide a place where a semiconductor substrate W, such as a wafer, is chemically and mechanically polished, and an electrode 21 may be disposed below the polishing pad 22. In addition, the platen 20 may be rotated by a driving device such as a motor by connecting a rotating shaft 23 therebelow. For example, the driving device may cause the rotating shaft 23 to rotate in the rotation direction D1.

A power supply unit 24 may be connected to the electrode 21. The power supply unit 24 according to an example embodiment may include a DC power supply 25 and a pulse supply unit 26. However, the present inventive concept is not limited thereto, and the power supply unit 24 may include an AC power source. When the power supply unit 24 includes an AC power, the pulse supply unit 26 may be omitted.

The electrode 21 may be disposed to cover a lower portion of the polishing pad 22. In some embodiments, the electrode 21 may be disposed to completely cover a lower portion of the polishing pad 22. The electrode 21 may form an electrical field above the polishing pad 22 using power applied from the power supply unit 24. A distribution of the abrasive P2 and the additive P1 included in the slurry SL supplied on the polishing pad 22 may be adjusted by an electrical field formed by the electrode 21, and by using this, etching flatness of the polishing target film OL of the semiconductor substrate W may be improved. For example, the power supply unit 24 may adjust the supplied power to adjust intensity of the electrical field applied to the abrasive and the additive at the electrode. This will be described later in detail.

A semiconductor substrate W to be chemically and mechanically polished may be attached to a lower portion of the polishing head 30 by vacuum. The polishing head 30 may adhere the semiconductor substrate W to the polishing pad 22 with a constant pressure and may rotate by a rotation shaft 32 to chemically and mechanically polish the semiconductor substrate W. For example, the polishing head 30 may be installed on the polishing pad 22, and may rotate the semiconductor substrate W in close contact with the polishing pad 22. A polishing target film OL may be formed on the semiconductor substrate W, and the polishing target film OL may be a silicon oxide film. However, the present inventive concept is not limited thereto, and the polishing target film OL may be a metal film such as tungsten or copper, depending on example embodiments.

Referring to FIG. 2, a slurry supply unit 40 may be disposed to be spaced apart from the polishing head 30 in a rotation direction D1. The slurry supply unit 40 may spray a slurry SL to the polishing pad 22. The slurry SL sprayed from the slurry supply unit 40 may be discharged externally of the platen 20 after mechanically polishing the surface S of the polishing target film OL (see FIG. 1).

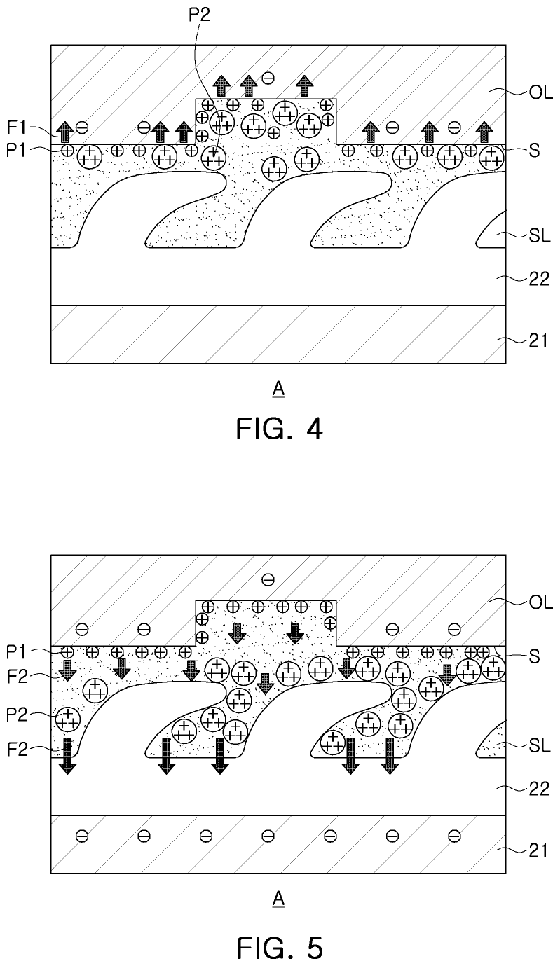

The slurry SL may include an abrasive P2 and an additive P1 (see FIGS. 4 and 5).

The abrasive P2 may mechanically polish a surface S of the polishing target film OL of the semiconductor substrate W. The abrasive may be a composition including any one of silica, alumina, or ceria.

The additive P1 may be adsorbed on the surface S of the polishing target film OL of the semiconductor substrate W, to cover a surface of the semiconductor substrate W. Examples of the additive (P1) may include potassium hydroxide, sodium hydroxide, ammonium hydroxide, and amine-based compounds. These can be used individually or in mixture thereof

Referring to FIGS. 4, 5, 6, and 7A to 7C, by applying an electrical field to the slurry SL, a process of improving etch flatness of the semiconductor substrate W will be described.

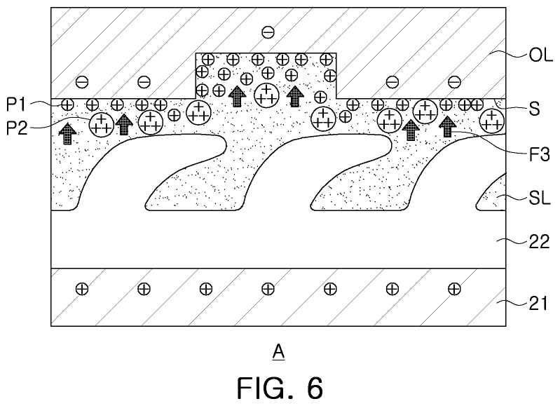

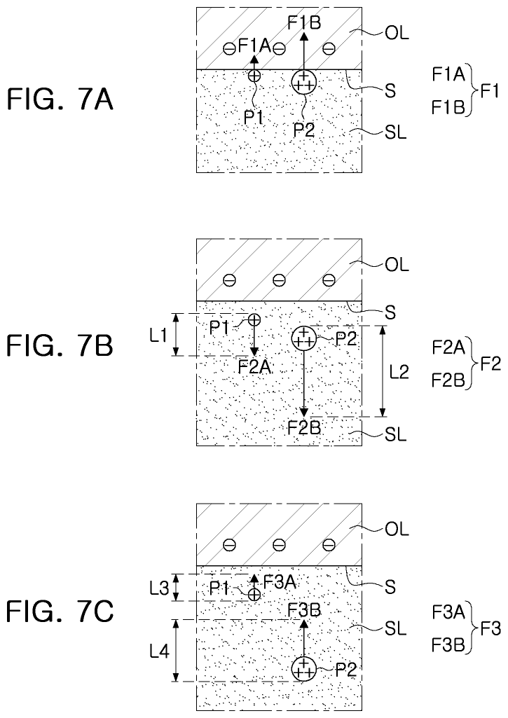

FIG. 5 is a diagram illustrating a process in which an abrasive and an additive move, when a pulse of a second polarity is applied to an electrode, and FIG. 4 is a diagram illustrating a process in which the abrasive and the additive move, when a pulse is not applied to an electrode. FIG. 6 is a diagram illustrating a process in which an abrasive and an additive move, when a pulse of a first polarity is applied to an electrode, and FIGS. 7A to 7C are diagrams specifically illustrating a process in which the abrasive and the additive are adsorbed on a surface of the polishing target film when pulses of a first polarity and a second polarity are applied.

In an example embodiment, a case in which the polishing target film OL is a silicon oxide film, the abrasive P2 is ceria, and the additive P1 is an amine-based compound, will be described as an example. Referring to FIGS. 4 and 7A, when the slurry SL has a pH of 7 or higher, a surface S of the polishing target film OL formed of a silicon oxide film may have a zeta potential of (−) polarity. In addition, surfaces of the abrasive P2 and the additive P1 may have a zeta potential of (+) polarity. Therefore, when no power is applied to the electrode 21, electrical attractive forces F1B and F1A may act on the abrasive P2 and the additive P1 having a zeta potential of (+) polarity, respectively, and the abrasive P2 and the additive P1 may be adsorbed to the polishing target film OL having a zeta potential of (−) polarity.

Referring to FIG. 5, when power of (−) polarity is applied to the electrode 21, the abrasive P2 and the additive P1 may move in a direction of the polishing pad 22. Rates at which the abrasive P2 and the additive P1 move are different from each other, which is related to charge density of the abrasive P2 and the additive P1. This will be described with reference to FIG. 7B. When power of (−) polarity is applied to the electrode 21, electrical attractive forces F2B and F2A may act on the abrasive P2 and the additive P1, respectively, and move in a direction of the polishing pad 22. When the charge density of the abrasive P2 is designed to be larger than the charge density of the additive P1, electrical attractive force F2B acting on the abrasive P2 is greater than electrical attractive force F2A acting on the additive P1 having relatively low charge density. As a result, a second distance L2 in which the abrasive P2 moves by the electrical field applied from the electrode 21 may be relatively greater than a first distance L1 in which the additive P1 moves. As described above, since the abrasive P2 moves in a direction of the electrode 21 faster than the additive P1, by adjusting a time for which an electrical field is applied to the abrasive P2 and the additive P1, a vertical distribution of the abrasive P2 and the additive P2 may be controlled. That is, as illustrated in FIG. 5, the abrasive P2 may be adsorbed to a surface of the polishing pad 22, and the additive P1 may be controlled to be adsorbed to a surface of the polishing target film OL. However, when a time for which an electrical field is applied to the abrasive P2 and the additive P1 is longer than a predetermined time, the additive P1 may be adsorbed to the surface of the polishing pad 22 by the electrical attractive force F2A acting on the additive P1. Therefore, in order to prevent this, it is necessary to apply power of (−) polarity to the electrode 21 for a period of time such that the additive P1 can be adsorbed to the surface of the polishing target film OL while the abrasive P2 is adsorbed to the polishing pad 22. A relationship between a time that an electrical field is applied to the slurry SL and a distribution of the abrasive P2 and the additive P1 can be measured experimentally, and based on this, a time for which power is applied to the electrode 21 may be calculated.

For example, when a DC pulse is applied to the electrode 21, a vertical distribution of the abrasive P2 and the additive P1 may be adjusted by appropriately adjusting a magnitude and frequency of the pulse. For example, the magnitude of the applied DC pulse may be adjusted in a range of 1000 V or less, and the frequency of the DC pulse may be adjusted in a range of 10 Hz to 1000 Hz. In addition, when an alternating current is applied to the electrode 21, a vertical distribution of the abrasive P2 and the additive P1 may be adjusted by adjusting a magnitude and frequency of the alternating current. For example, the magnitude of the applied AC current may be adjusted in a range of 1000 V or less, and the frequency of the AC may be adjusted in the range of 10 Hz to 1000 Hz.

Conversely, as shown in FIG. 6, when power of a (+) polarity is applied to the electrode 21, electrical repulsive forces F3A and F3B are applied to the abrasive P2 and the additive P1, respectively, and the abrasive P2 and the additive P1 move in a direction of the polishing target film (OL). Accordingly, as shown in FIG. 7C, an additive P1 relatively distributed adjacent to the polishing target film OL is adsorbed to a surface S of the polishing target film OL by moving a third distance L3, and an abrasive P2 distributed relatively far from the polishing target film OL is not adsorbed to the surface S of the polishing target film OL even when it moves a fourth distance L4, longer than the third distance L3. Accordingly, the distribution of the abrasive P2 may increase in a direction in which the polishing pad 22 is disposed in the polishing target film OL.

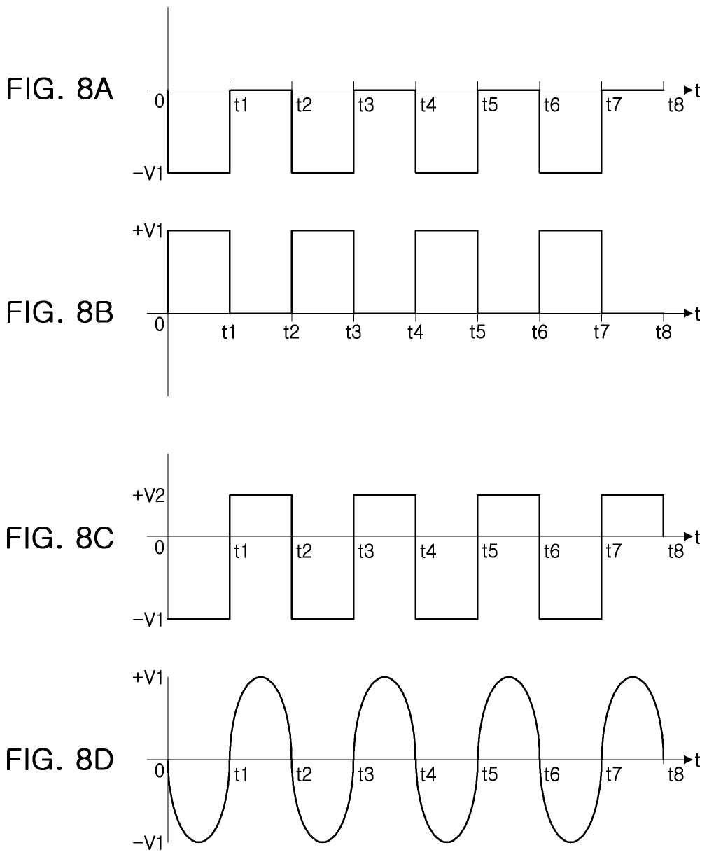

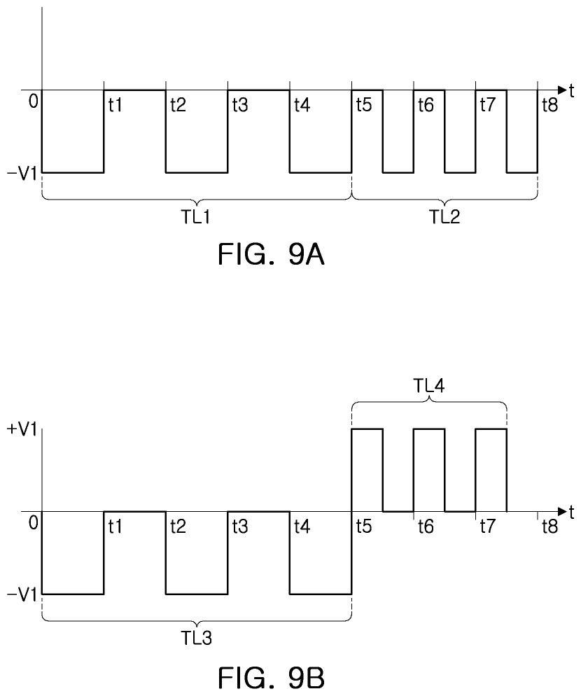

FIGS. 8A to 8D illustrate various examples of a current applied to an electrode, and FIGS. 9A and 9B illustrate modified examples of a current applied to an electrode.

A DC pulse shown in FIG. 8A may be applied when a surface S of a polishing target film OL has a zeta potential of (−) polarity and surfaces of an abrasive P2 and an additive P1 have a zeta potential of (+) polarity. In this case, the abrasive P2 and the additive P1 move in a direction of the polishing pad 22 during a time period during which a pulse is applied (0 to t1, t2 to t3, t4 to t5, t6 to t7), but the abrasive P2 and the additive P1 move in a direction of the polishing target film OL during a time period during which a pulse is not applied (t1 to t2, t3 to t4, t5 to t6), so that a vertical distribution of the abrasive P2 and the additive P1 may be adjusted. Here, magnitude −V1 is a magnitude of the pulse of the (−) polarity.

Conversely, a DC pulse illustrated in FIG. 8B may be applied when a surface S of the polishing target film OL has a zeta potential of (+) polarity and surfaces of the abrasive P2 and the additive P1 have a zeta potential of (−) polarity. Since a process of adjusting the vertical distribution of the abrasive P2 and the additive P1 is the same as that of FIG. 8A, a detailed description thereof will be omitted. Here, magnitude +V1 is a magnitude of the pulse of the (+) polarity.

A DC pulse shown in FIG. 8C may be applied, when a surface S of the polishing target film OL has a zeta potential (−) polarity and surfaces of the abrasive P2 and the additive P1 have a zeta potential of (+) polarity. The pulse of FIG. 8C shows a case in which a pulse of (−) polarity and a pulse of (+) polarity are alternated, but a magnitude of the pulse of the (+) polarity is lower than a magnitude of the pulse of the (−) polarity. The magnitude V2 of the pulse of the (+) polarity may be 50V or more lower than the magnitude V1 of the pulse of the (−) polarity. In this case, the abrasive P2 and the additive P1 move toward the polishing pad 22 during a time period during which the pulse of (−) polarity is applied (0 to t1, t2 to t3, t4 to t5, t6 to t7), but the abrasive P2 may be separated from the polishing pad 22 and removed during a time period during which the pulse of (+) polarity is applied (t1 to t2, t3 to t4, t5 to t6), such that the abrasive P2 adsorbed to the polishing pad 22 may be newly replaced every hour.

In an alternating current shown in FIG. 8D, similar to FIG. 8C, the abrasive P2 and the additive P1 move toward the polishing pad 22 during a time period during which, when a current of (−) polarity (0 to t1, t2 to t3, t4 to t5, t6 to t7) is applied, the abrasive P2 may be separated from the polishing pad 22 and removed during a time period during which a current of (+) polarity (t1 to t2, t3 to t4, t5 to t6) is applied, such that the abrasive P2 adsorbed to the polishing pad 22 may be newly replaced every hour.

FIGS. 8C and 8D illustrate embodiments in which a voltage supply unit (e.g., power supply unit 24) applies a voltage of a first polarity and a voltage of a second polarity, opposite to the first polarity, to an electrode (e.g., electrode 21) to adjust intensity of an electrical field applied to the abrasive and the additive at the electrode.

A DC pulse shown in FIG. 9A is similar to the pulse shown in FIG. 8A, but there is a difference in that the frequency applied during the first time period TL1 is different from the frequency of the pulse applied during the second time period TL2.

A DC pulse shown in FIG. 9B is similar to the pulse shown in FIG. 8A, but there is a difference in that the magnitude, frequency, and polarity of the pulse applied during the first time period TL3 are different from the magnitude, frequency, and polarity of the pulse applied during the second time period TL4. Similar to the pulse of FIG. 8D, the abrasive material P2 adsorbed to the polishing pad 22 is replaced, but there is a difference in that a replacement cycle of the abrasive material P2 is longer than that of FIG. 8D.

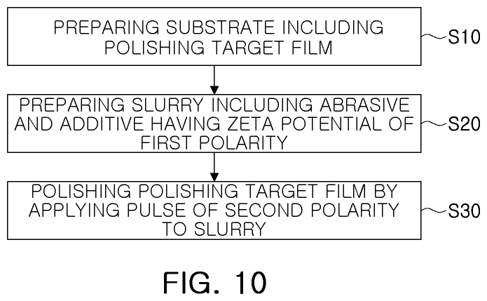

Next, a chemical mechanical polishing method according to an example embodiment will be described with reference to FIG. 10. FIG. 10 is a flowchart schematically illustrating a chemical mechanical polishing method according to an example embodiment. The chemical mechanical polishing method of FIG. 10 is a process using the chemical mechanical polishing apparatus of FIGS. 1 and 2, and detailed description of the configuration described in FIGS. 1 and 2 will be omitted.

First, a semiconductor substrate on which a polishing target film OL is formed may be prepared (S10). In an example embodiment, the polishing target film OL may be a silicon oxide film. Alternatively, according to an example embodiment, the polishing target film OL may be a metal film such as tungsten or copper.

The polishing target film OL may have a zeta potential, opposite to a first polarity, which will be described later. A semiconductor substrate W may be attached to the polishing head 30 of FIG. 2 by vacuum.

Next, a slurry including an abrasive and an additive having a zeta potential of a first polarity may be prepared (S20). An abrasive P2 may include any one of silica, alumina, and ceria. Examples of an additive (P1) may be potassium hydroxide, sodium hydroxide, ammonium hydroxide, amine-based compounds, and the like. These can be used individually or in mixture thereof. In an example embodiment, the abrasive P2 may be ceria, and the additive P1 may be an amine-based compound. In this case, by measuring the zeta potential of the abrasive P2 and the additive P1, a magnitude and frequency of a current of a second polarity applied to a slurry SL may be determined.

Next, a polishing target film may be polished by applying a current of a second polarity to a slurry SL (S30). In an example embodiment, the polishing target film OL may be polished by spraying the slurry SL to the platen 20 of FIG. 2 and applying a DC pulse having a second polarity, opposite to the first polarity. The current of the second polarity may be a DC pulse current or an AC current. A magnitude of the DC pulse may be adjusted in a range of 1000 V or less, and a frequency of the DC pulse may be adjusted in a range of 10 Hz to 1000 Hz. In addition, a magnitude of the alternating current may be adjusted in a range of 1000V or less, and a frequency of the alternating current may be adjusted in a range of 10 Hz to 1000 Hz.

As set forth above, according to an example embodiment of the present inventive concept, it is possible to provide a chemical mechanical polishing apparatus and a method using the same having improved flatness efficiency of a polishing target film in a CMP process.

Herein, a lower side, a lower portion, a lower surface, and the like, are used to refer to a direction toward a mounting surface of the fan-out semiconductor package in relation to cross-sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only in order to describe example embodiments rather than limiting the present disclosure. In this case, singular forms include plural forms unless interpreted otherwise in context.

The various and advantageous advantages and effects of the present inventive concept are not limited to the above description, and may be more easily understood in the course of describing the specific embodiments of the present inventive concept.

While example embodiments have been shown and described above, it will be apparent to those skilled in the art that modifications and variations could be made without departing from the scope of the present inventive concept as defined by the appended claims.

1. A chemical mechanical polishing apparatus, comprising:
a platen having a polishing pad attached to an upper surface thereof, and rotatably installed in one direction by a driving means;
a slurry supply unit configured to supply a slurry including an abrasive and an additive having a zeta potential of a first polarity to the polishing pad;
an electrode disposed below the polishing pad;
a power supply unit configured to apply a voltage including a DC pulse of a second polarity, opposite to the first polarity, to the electrode; and
a polishing head installed on the polishing pad, and configured to rotate a semiconductor substrate in contact with the polishing pad.

2. The chemical mechanical polishing apparatus of claim 1, wherein a magnitude of the DC pulse is 1000V or less, and a frequency of the DC pulse is 10 Hz to 1000 Hz.

3. The chemical mechanical polishing apparatus of claim 1, wherein the voltage further comprises a DC pulse of the first polarity.

4. The chemical mechanical polishing apparatus of claim 3, wherein the DC pulse of the first polarity alternates with the DC pulse of the second polarity.

5. The chemical mechanical polishing apparatus of claim 4, wherein a magnitude of the DC pulse of the first polarity is lower than a magnitude of the DC pulse of the second polarity.

6. The chemical mechanical polishing apparatus of claim 5, wherein the magnitude of the DC pulse of the first polarity is at least 50V lower than the magnitude of the DC pulse of the second polarity.

7. The chemical mechanical polishing apparatus of claim 3, wherein the voltage comprises a first time period to which the DC pulse of the first polarity is applied and a second time period to which the DC pulse of the second polarity is applied.

8. The chemical mechanical polishing apparatus of claim 1, wherein the abrasive is a composition including at least one of silica, alumina, and ceria.

9. The chemical mechanical polishing apparatus of claim 1, wherein the additive is a composition including any one of potassium hydroxide, sodium hydroxide, ammonium hydroxide, and an amine-based compound.

10. The chemical mechanical polishing apparatus of claim 1,
wherein the semiconductor substrate comprises a polishing target film having a zeta potential of the second polarity, and
wherein the polishing target film is disposed toward the polishing pad.

11. The chemical mechanical polishing apparatus of claim 10, wherein the semiconductor substrate is a silicon oxide film.

12. A chemical mechanical polishing apparatus, comprising:
a platen having a polishing pad attached to an upper surface thereof;
a slurry supply unit configured to supply a slurry including an abrasive and an additive having a zeta potential of a first polarity to the polishing pad;
an electrode disposed below the polishing pad;
a voltage supply unit configured to apply a voltage of a second polarity, opposite to the first polarity, to the electrode, the voltage supply unit configured to adjust the voltage to adjust intensity of an electrical field applied to the abrasive and the additive at the electrode; and
a polishing head installed on the polishing pad, and configured to rotate a semiconductor substrate in contact with the polishing pad,
wherein the abrasive and the additive have different vertical distributions between the polishing pad and the semiconductor substrate by the electrical field.

13. The chemical mechanical polishing apparatus of claim 12,
wherein the semiconductor substrate comprises a polishing target film having a zeta potential of the second polarity, and
wherein the polishing target film is disposed toward the polishing pad.

14. The chemical mechanical polishing apparatus of claim 13, wherein charge density of the abrasive is greater than charge density of the additive.

15. The chemical mechanical polishing apparatus of claim 14, wherein the additive is adsorbed to a surface of the polishing target film by the zeta potential of the second polarity of the polishing target film.

16. The chemical mechanical polishing apparatus of claim 15, wherein the abrasive is adsorbed to a surface of the polishing pad.

17. The chemical mechanical polishing apparatus of claim 12, wherein the first polarity is a + polarity, and the second polarity is a − polarity.

18. A chemical mechanical polishing apparatus, comprising:
a platen having a polishing pad attached to an upper surface thereof;
a slurry supply unit configured to supply a slurry including an abrasive and an additive having a zeta potential of a first polarity to the polishing pad;
an electrode disposed below the polishing pad;
a power supply configured to apply a voltage of the first polarity and a voltage of a second polarity, opposite to the first polarity, to the electrode; and
a polishing head installed on the polishing pad, and configured to rotate a semiconductor substrate including a polishing target film having a zeta potential of the second polarity in contact with the polishing pad,
wherein the power supply unit is configured to alternately apply a voltage of the first polarity and a voltage of the second polarity.

19. The chemical mechanical polishing apparatus of claim 18, wherein the voltage of the first polarity and the voltage of the second polarity are DC pulse voltages, respectively.

20. The chemical mechanical polishing apparatus of claim 19, wherein a magnitude of the voltage of the first polarity is at least 50V lower than a magnitude of the voltage of the second polarity.

21.-24. (canceled)
